(19) United States
(12) Patent Application Publication
(10) Pub. No.: US 2020/0395334 A1
(43) Pub. Date: Dec. 17, 2020

(54) Method and Structure for Supporting Thin Semiconductor Chips with a Metal Carrier

(71) Applicant: Infineon Technologies AG, Neubiberg (DE)

(72) Inventors: Joachim Mahler, Regensburg (DE); Michael Bauer, Nittendorf (DE); Christoph Liebl, Munich (DE); Georg Meyer-Berg, Munich (DE); Georg Reuther, Munich (DE); Peter Strobel, Regensburg (DE)

(21) Appl. No.: 16/437,978

(22) Filed: Jun. 11, 2019

(51) Int. Cl. H01L 23/00; H01L 21/78; H01L 21/48; H01L 23/495

(52) U.S. Cl. CPC H01L 24/94; H01L 24/83; H01L 21/78; H01L 21/4842; H01L 24/32; H01L 23/49513; H01L 2224/29021; H01L 2224/32258; H01L 2224/83192; H01L 2924/10157; H01L 2224/83365; H01L 2224/83191; H01L 2224/33181; H01L 24/33

(57) ABSTRACT

Disclosed is a method that includes: providing semiconductor dies, each of the semiconductor dies having a thinner active region surrounded by a thicker inactive region so that each of the semiconductor dies has a first cavity vertically aligned with the thinner active region and laterally surrounded by the thicker inactive region; providing a metal carrier having connection parts secured to the metal carrier, each of the connection parts dimensioned to fit within the first cavity of one of the semiconductor dies; inserting each of the connection parts of the metal carrier into the respective first cavity of the corresponding semiconductor die; after the inserting, attaching the metal carrier to the semiconductor dies; and after the attaching, singulating the metal carrier so that each of the connection parts of the metal carrier remains attached to the corresponding semiconductor die.

### BACKGROUND

A number of factors complicate the electrical interconnect of a metal clip to a semiconductor die (chip), particularly with regard to thin dies (<<100 μm). For example, improved heat dissipation, lower on-state resistance (RDSon), and a reliable adhesive, solder, and/or metal paste clip-attach process with a reduced risk of chip cracks during die pick-up and during exposure to thermo-mechanical package stress factor into the electrical interconnect of a metal clip to a semiconductor die.

A metal clip is typically attached at the front side of a thin semiconductor die by solder, adhesive or other paste interconnects. The backside of the thin semiconductor die is typically attached to a chip carrier such as a lead frame, a PCB (printed circuit board) or a ceramic based board using solders, adhesives or other paste interconnects.

Along with shrinking die thickness and dimensions, the common methods of die attach, soldering, adhesive die attach, sinter paste die attach and/or diffusion soldering are becoming more and more critical with regard to mechanical robustness and risk of die cracks, respectively.

The thinner the die, the more difficult the handling and application of die attach due to the brittleness of the very thin semiconductor material. Furthermore, in the assembled package, thermomechanical stress exerted by the metal clip on the thin semiconductor die attached to metal clip is higher the thinner the die, at least for die thickness <100 μm, and the thicker the metal clip. At the same time, the metal clip is required for lower electrical resistance and better heat dissipation.

Thus, there is a need for an improved method and structure for supporting thin semiconductor chips with a metal carrier.

### SUMMARY

According to an embodiment of a method, the method comprises: providing a plurality of semiconductor dies, each of the semiconductor dies having a thinner active region surrounded by a thicker inactive region so that each of the semiconductor dies has a first cavity vertically aligned with the thinner active region and laterally surrounded by the thicker inactive region; providing a metal carrier having connection parts secured to the metal carrier, each of the connection parts dimensioned to fit within the first cavity of one of the semiconductor dies; inserting each of the connection parts of the metal carrier into the respective first cavity of the corresponding semiconductor die; after the inserting, attaching the metal carrier to the semiconductor dies; and after the attaching, singulating the metal carrier so that each of the connection parts of the metal carrier remains attached to the corresponding semiconductor die.

The metal carrier may be a leadframe and the connection parts of the metal carrier may be raised parts of die pads of the leadframe. Inserting each of the connection parts of the metal carrier into the respective first cavity of the corresponding semiconductor die may comprise: applying a die attach material to the raised parts of the die pads of the leadframe; and after applying the die attach material, inserting each of the raised parts into the respective first cavity of the corresponding semiconductor die.

Separately or in combination, the method may further comprise: before the inserting, forming a thin metallization layer on a surface of the thinner active region facing the first cavity of each of the semiconductor dies.

Separately or in combination, the method may further comprise: forming the thin metallization layer on sidewalls of the thicker inactive region facing the first cavity of each of the semiconductor dies.

Separately or in combination, the method may further comprise: before the inserting, applying a solder paste to a side of each of the semiconductor dies with the first cavity, including on a surface of the thinner active region facing the first cavity of each of the semiconductor dies and on sidewalls of the thicker inactive region facing the first cavity of each of the semiconductor dies.

Separately or in combination, the method may further comprise: before the inserting, rounding interior corners of the first cavity of each of the semiconductor dies.

Separately or in combination, the raised parts of the die pads of the leadframe may bend upward in a direction towards the semiconductor dies so as to not have a local increase in thickness in a region adjacent to the thinner active regions of the semiconductor dies.

Separately or in combination, the metal carrier may be a leadframe and the connection parts of the metal carrier may be surrounded by grooves formed in the leadframe. Inserting each of the connection parts of the metal carrier into the respective first cavity of the corresponding semiconductor die may comprise: applying a die attach material to a side of the leadframe with the grooves, including in the grooves; and after applying the die attach material, inserting the thicker inactive region of each of the semiconductor dies into the groove surrounding the corresponding connection part of the leadframe to which the semiconductor die is to be attached.

Separately or in combination, the grooves may extend through the leadframe from a first main surface of the leadframe to a second main surface of the leadframe opposite the first main surface. Inserting each of the connection parts of the metal carrier into the respective first cavity of the corresponding semiconductor die may comprise: inserting the thicker inactive region of each of the semiconductor dies into the groove surrounding the corresponding connection part of the leadframe to which the semiconductor die is to be attached.

Separately or in combination, the method may further comprise: after the inserting, filling gaps in the grooves unoccupied by the thicker inactive region of the semiconductor dies with an electrically insulating material. The electrically insulating material may be a mold compound.

Separately or in combination, the method may further comprise: after the inserting, encapsulating the semiconductor dies and a side of the leadframe to which the semiconductor dies are attached with an encapsulation material.

Separately or in combination, inserting each of the connection parts of the metal carrier into the respective first cavity of the corresponding semiconductor die may comprise: applying a first electrically conductive material to a top side, an outer edge and a bottom side of the semiconductor dies, to provide an electrical connection to the top side from the bottom side of the semiconductor dies; applying a second electrically conductive material to a surface of the thinner active region facing the first cavity of each of the semiconductor dies, the second electrically conductive material being electrically isolated from the first electrically conductive material; and after applying the first and the second electrically conductive materials, inserting the thicker inactive region of each of the semiconductor dies into the groove surrounding the corresponding connection part of the leadframe to which the semiconductor die is to be attached.

Separately or in combination, the method may further comprise: after the inserting, encapsulating the semiconductor dies and a side of the leadframe to which the semiconductor dies are attached with an encapsulation material.

Separately or in combination, the method may further comprise: forming a second cavity in each of the semiconductor dies at an opposite side of the semiconductor dies as the first cavity, the second cavity being vertically aligned with the thinner active region and the first cavity and laterally surrounded by the thicker inactive region; and inserting a separate metal clip into the respective second cavity of each of the semiconductor dies.

According to an embodiment of a semiconductor device, the semiconductor device comprises: a semiconductor die having a thinner active region surrounded by a thicker inactive region, and a first cavity vertically aligned with the thinner active region and laterally surrounded by the thicker inactive region; and a die pad of a leadframe positioned at least partly within the first cavity so as to at least partly occupy the first cavity, the die pad being attached to the semiconductor die.

The semiconductor die may have a second cavity at an opposite side of the semiconductor die as the first cavity, the second cavity may be vertically aligned with the thinner active region and the first cavity and laterally surrounded by the thicker inactive region, the semiconductor device may further comprise a metal clip positioned at least partly within the second cavity so as to at least partly occupy the second cavity, and the metal clip may be attached to the semiconductor die. The metal clip may extend over the thicker inactive region of the semiconductor die and has a notch extending into the second cavity.

According to another embodiment of a semiconductor device, the semiconductor device comprises: a leadframe; a semiconductor die attached to the leadframe in a flip-chip configuration with a front side of the semiconductor die facing the leadframe, the semiconductor die having a thinner active region surrounded by a thicker inactive region, and a cavity formed in a backside of the semiconductor die, the cavity being vertically aligned with the thinner active region and laterally surrounded by the thicker inactive region; and a metal clip inserted in the cavity and attached to the backside of the semiconductor die. The semiconductor die may be a vertical power transistor die. In one embodiment, the metal clip provides a drain connection to the backside of the semiconductor die and provides top-side cooling for the semiconductor device. Separately or in combination, the leadframe may be segmented into a plurality of separate sections, a first section of the plurality of separate sections may provide a source connection to the semiconductor die, and a second section of the plurality of separate sections may provide a gate connection to the semiconductor die.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a flow diagram of an embodiment of a method for supporting thin semiconductor dies with a metal carrier.

FIGS. 2A through 2C illustrate respective cross-sectional views of an embodiment of Blocks 110 through 130 of the method shown in FIG. 1.

FIGS. 3A through 3F illustrate respective cross-sectional views of another embodiment of Blocks 110 through 130 of the method shown in FIG. 1.

FIGS. 4A through 4F illustrate respective cross-sectional views of another embodiment of Blocks 110 through 130 of the method shown in FIG. 1.

FIGS. 5A through 5C illustrate respective cross-sectional views of another embodiment of Blocks 120 through 140 of the method shown in FIG. 1.

FIGS. 6A through 6C illustrate respective cross-sectional views of another embodiment of Blocks 110 through 130 of the method shown in FIG. 1.

FIGS. 7A through 7C illustrate respective cross-sectional views of another embodiment of Blocks 110 through 130 of the method shown in FIG. 1.

FIGS. 8A and 8B illustrate respective cross-sectional views of another embodiment of Blocks 110 through 130 of the method shown in FIG. 1.

FIGS. 9A through 9D illustrate respective cross-sectional views of another embodiment of Blocks 110 through 130 of the method shown in FIG. 1.

FIGS. 10A through 100 illustrate respective cross-sectional views of another embodiment of Blocks 110 through 130 of the method shown in FIG. 1.

FIGS. 11-13 illustrates respective side perspective views of additional embodiments of Blocks 110 through 130 of the method shown in FIG. 1.

### DETAILED DESCRIPTION

The embodiments described herein provide a chip (die) design and contact structure, and a complementarily adjusted structure type on the chip carrier to support the standard interconnect process as well as improved electrical and thermal conductivity of such an interconnect. For example, semiconductor dies are provided. The semiconductor dies may still be conjoined, i.e., attached to the same wafer from which the dies are produced. Instead, the semiconductor dies may already have been singulated, i.e., separated from the other dies produced from the same wafer. In either case, a cavity is formed in the center of the dies so that each die has a thinner active region surrounded by a thicker inactive region, the cavity being vertically aligned with the thinner active region and laterally surrounded by the thicker inactive region. The techniques described herein enables improved handling of thin dies, e.g., less than 180 μm (microns) thick, less than 100 μm thick, less than 60 μm thick, less than 40 μm thick. The electrically active area of each die is in the region of the cavity, and the thicker region is not electrically active but used for handling, pick-up, support, etc. Good electrical connection between the active area of each die and a metal carrier/interconnect such as a lead frame is provided, whereby the cavities form reliable containers for receiving a respective connection part of the metal carrier. The cavities may be at the front and/or back side of the dies. After the connection parts of the metal carrier are inserted into the respective cavity of the semiconductor dies and after the metal carrier is attached to the semiconductor dies, the metal carrier (and the wafer, if the dies have yet to be separated from one another) is singulated so that each of the connection parts of the metal carrier remains attached to the corresponding semiconductor die in separate package assemblies.

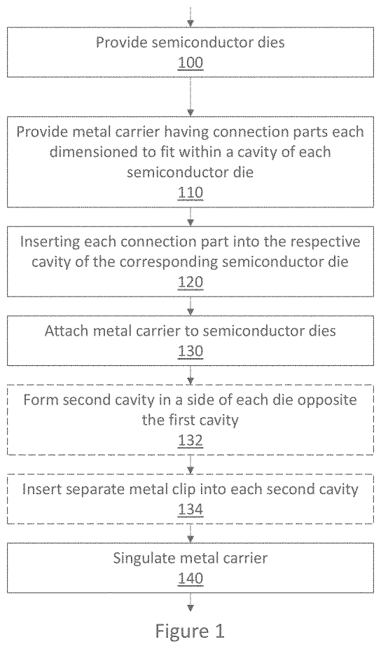

FIG. 1 illustrates an embodiment of a method for supporting thin semiconductor dies with a metal carrier. The method includes providing a plurality of semiconductor dies (Block 100). The semiconductor dies may still be conjoined in that the dies have yet to be physically separated from one another. Alternatively, the semiconductor dies may already have been singulated, i.e., separated from the other dies produced from the same wafer. In either case, any type of semiconductor wafer may be used to form the semiconductor dies. For example, the semiconductor wafer may be a Si wafer, a SiC wafer, a GaN wafer, etc.

Each of the semiconductor dies has a thinner active region surrounded by a thicker inactive region so that each of the semiconductor dies has a first cavity vertically aligned with the thinner active region and laterally surrounded by the thicker inactive region. The die cavities may be formed by wet etching, dry etching, plasma etching, electrical discharge machining (EDM) or a variant of EDM, electrochemical etching, etc.

The method further includes providing a metal carrier having connection parts secured to the metal carrier, each of the connection parts dimensioned to fit within the first cavity of one of the semiconductor dies (Block 110). In one embodiment, the metal carrier is a leadframe and the connection parts of the metal carrier are raised parts of die pads of the leadframe. Still other types of metal carriers could be used, such as a metallized region of a PCB or a ceramic-based board.

The method further includes inserting each of the connection parts of the metal carrier into the respective first cavity of the corresponding semiconductor die (Block 120). A die attach material such as solder paste, sinter paste, an adhesive, etc. may be placed in the die cavities and/or on the connection parts of the metal carrier, to facilitate attachment of the metal carrier to the semiconductor dies.

After each of the connection parts of the metal carrier are inserted into the respective first cavity of the corresponding semiconductor die, the metal carrier is attached to the semiconductor dies (Block 130). The metal carrier is attached to the semiconductor dies by the die attach material previously placed in the die cavities and/or on the connection parts of the metal carrier.

After attaching the metal carrier to the semiconductor dies, the metal carrier is singulated so that each of the connection parts of the metal carrier remains attached to the corresponding semiconductor die (Block 140). Any typical singulation process such as sawing with a blade, EDM, laser dicing, plasma dicing, etc. may be used to singulate the metal carrier into separate package assemblies. If the semiconductor dies have yet to be separated from one another, the wafer is also singulated.

As indicated by the dashed boxes in FIG. 1, the method may further include forming a second cavity in each of the semiconductor dies at an opposite side of the semiconductor dies as the first cavity, the second cavity being vertically aligned with the thinner active region and the first cavity and laterally surrounded by the thicker inactive region (Block 132), and inserting a separate metal clip into the respective second cavity of each of the semiconductor dies (Block 134). If optional Blocks 132 and 134 are performed, each semiconductor die will have a connection part of a metal carrier, such as a die pad of a leadframe, positioned at least partly within the respective first cavity and a metal clip positioned at least partly within the second cavity.

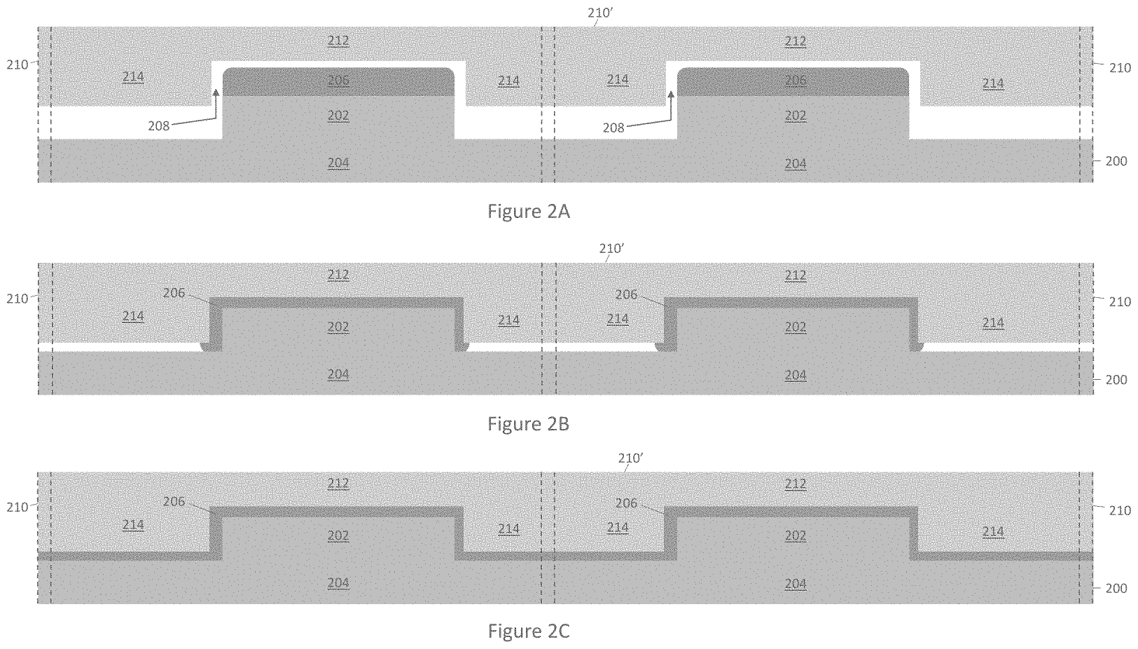

The method described above and variations thereof are explained below in more detail with reference to FIGS. 2A through 10C.

FIGS. 2A through 2C illustrate an embodiment of Blocks 110 through 130 of the method shown in FIG. 1, wherein the metal carrier is a leadframe 200. According to this embodiment, the connection parts of the metal carrier are raised parts 202 of die pads 204 of the leadframe 200 and inserting each of the connection parts of the metal carrier into the respective first cavity of the corresponding semiconductor die (Block 120 in FIG. 1) is carried out by applying a die attach material 206 to the raised parts 202 of the die pads 204 of the leadframe 200, as shown in FIG. 2A. The die attach material 206 may be solder paste, sinter paste, an adhesive, etc.

After applying the die attach material 206, the semiconductor wafer 210′ is positioned over the leadframe 200 so that each of the raised parts 202 of the die pads 204 of the leadframe 200 is vertically aligned with the respective first cavity 208 of the corresponding semiconductor die 210, as shown in FIG. 2A.

The semiconductor wafer 210′ is then placed on the leadframe 200 so that each of the raised parts 202 of the die pads 204 of the leadframe 200 inserts into the respective first cavity 208 of the corresponding semiconductor die 210, as shown in FIG. 2B. The first cavity 208 of each semiconductor die 210, which is vertically aligned with the thinner active region 212 and laterally surrounded by the thicker inactive region 214 of the die 210, forms a type of container for receiving the die attach material 206. Depending on the amount of die attach material 206 used, some of the die attach material 206 may be pressed out of the die cavities 208 and onto the non-raised parts of the die pads 204.

After each of the raised parts 202 of the die pads 204 of the leadframe 200 is inserted into the respective first cavity 208 of the corresponding semiconductor die 210, the leadframe 200 is attached to the semiconductor dies 210 by soldering, sintering, gluing, etc., as shown in FIG. 2C. In the case of a thermally conductive and electrically insulative die attach material 206, a good (direct) thermal connection is formed between the thinner active region 212 of each semiconductor die 210 and the leadframe 200. In the case of a thermally and electrically conductive die attach material 206, a good (direct) thermal and electrical connection is formed between the thinner active region 212 of each semiconductor die 210 and the leadframe 200. The pairs of dashed lines in FIGS. 2A through 2C indicate the dicing streets which are cut, diced, machined, etc. to singulate the leadframe 200 and the semiconductor dies 210 if the dies 210 have yet to been singulated from the wafer 210 (Block 140 in FIG. 1). If the semiconductor dies 210 were singulated prior to attachment to the leadframe 200, only the leadframe 200 is singulated to form separate package assemblies.

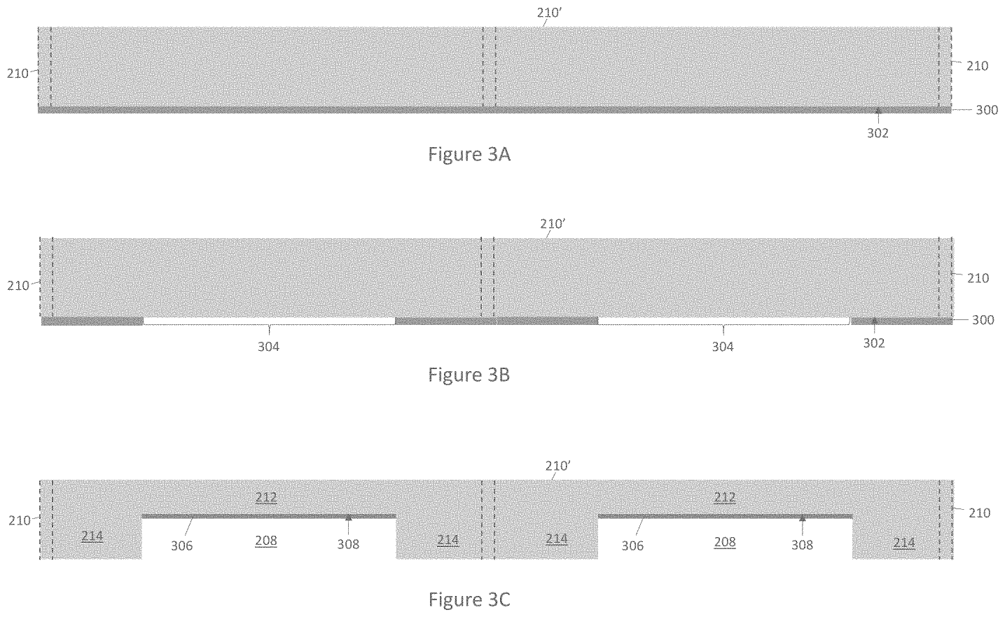

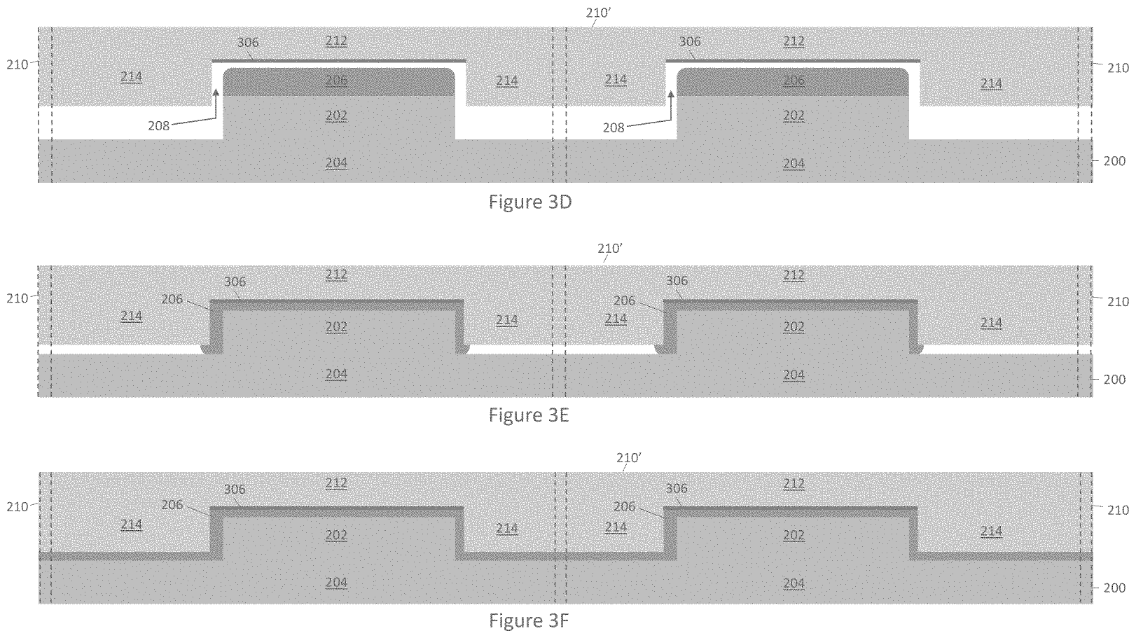

FIGS. 3A through 3F illustrate another embodiment of Blocks 110 through 130 of the method shown in FIG. 1, wherein the metal carrier is a leadframe 200. According to this embodiment, the first cavities 208 are formed in the semiconductor dies 210 by depositing an etch mask 300 on the back side 302 of the semiconductor wafer 210′, as shown in FIG. 3A.

The etch mask 300 is then patterned to expose regions 304 of the back side 302 of the semiconductor wafer 210′ to be etched, as shown in FIG. 3B.

The exposed regions 304 of the back side 302 of the semiconductor wafer 210′ are then etched to form the first cavities 208 in the semiconductor dies 210, as shown in FIG. 3C. The etch mask 300 may be removed after the first die cavities 208 are formed. The type of etch mask 300 and processes used to pattern the etch mask 300 and etch into the exposed regions 304 of the back side 302 of the semiconductor wafer 210′ depends on the type of semiconductor material used.

Before placing the semiconductor wafer 210′ on the leadframe 200, a thin metallization layer 306 is formed on the (exposed) surface 308 of the thinner active region 212 facing the first cavity 208 of each of the semiconductor dies 210. The metallization layer 306 may be a stack of different metals or a single metal layer with at least one of the metals being Ag, Cu, CuSn, Ni, NiSn, Sn, Al, Au or a combination thereof as the last metal layer for the exposed surface 308.

A die attach material 206 is applied to the raised parts 202 of the die pads 204 of the leadframe 200 and then the semiconductor wafer 210′ (or alternatively the singulated dies 210) is positioned over the leadframe 200 so that each of the raised parts 202 of the die pads 204 of the leadframe 200 is vertically aligned with the respective first cavity 208 of the corresponding semiconductor die 210, as shown in FIG. 3D. The semiconductor dies 210 are then placed on the leadframe 200 so that each of the raised parts 202 of the die pads 204 of the leadframe 200 inserts into the respective first cavity 208 of the corresponding semiconductor die 210, as shown in FIG. 3E. After each of the raised parts 202 of the die pads 204 of the leadframe 200 is inserted into the respective first cavity 208 of the corresponding semiconductor die 210, the leadframe 200 is attached to the semiconductor dies 210 by soldering, sintering, gluing, etc., as shown in FIG. 3F. The processes shown in FIGS. 3D through 3F are the same as the processes shown in FIGS. 2A through 2C, respectively. As such, no further description of FIGS. 3D through 3F is provided. As explained above in connection with FIGS. 1A through 10, the semiconductor dies 210 may be singulated prior to attachment to the leadframe 200 or as part of the leadframe singulation process to form separate package assemblies.

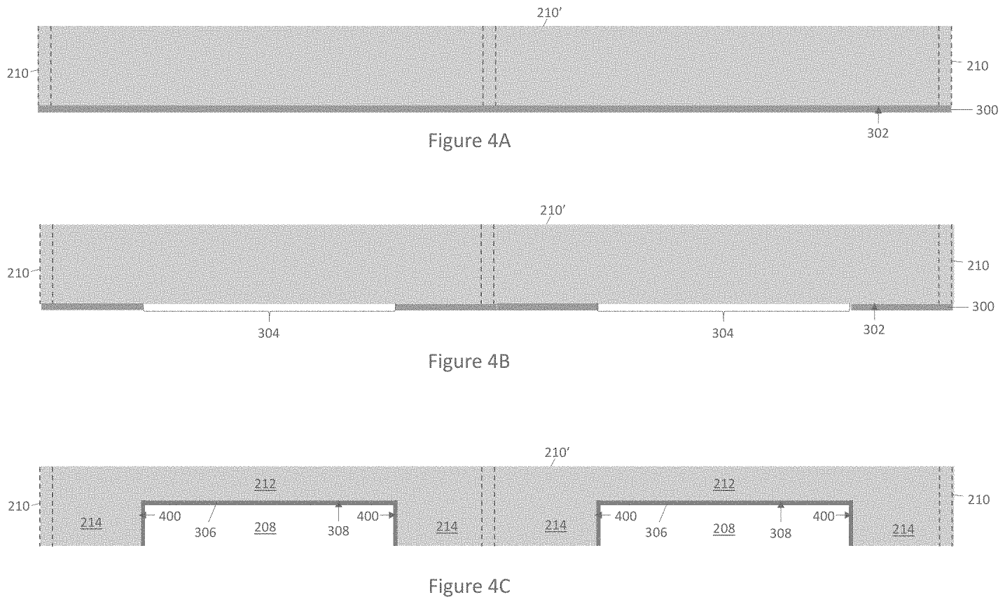

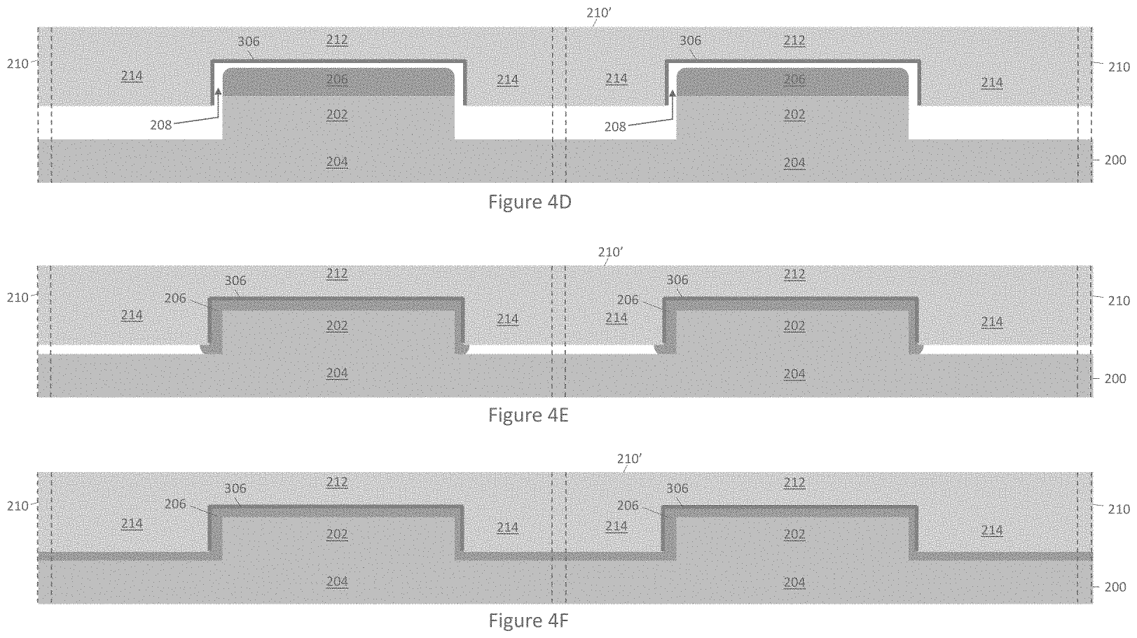

FIGS. 4A through 4F illustrate another embodiment of Blocks 110 through 130 of the method shown in FIG. 1, wherein the metal carrier is a leadframe 200. The processes shown in FIGS. 4A through 4C are similar to the processes shown in FIGS. 3A through 3C, respectively. Different, however, the thin metallization layer 306 is also formed on sidewalls 400 of the thicker inactive region 214 facing the first cavity 208 of each of the semiconductor dies 210. For example, in FIGS. 3A through 3C, the thin metallization layer 306 may not be deposited on the sidewalls 400 of the thicker inactive region 214, or may be deposited on the sidewalls 400 and subsequently removed from the sidewalls. This is in contrast to FIGS. 4A through 4F, in which the thin metallization layer 306 remains on the sidewalls 400 in the final product. The processes shown in FIGS. 4D through 4F are the same as the processes shown in FIGS. 2A through 2C, respectively. As such, no further description of FIGS. 4D through 4F is provided. As explained above in connection with FIGS. 1A through 10, the semiconductor dies 210 may be singulated prior to attachment to the leadframe 200 or as part of the leadframe singulation process to form separate package assemblies.

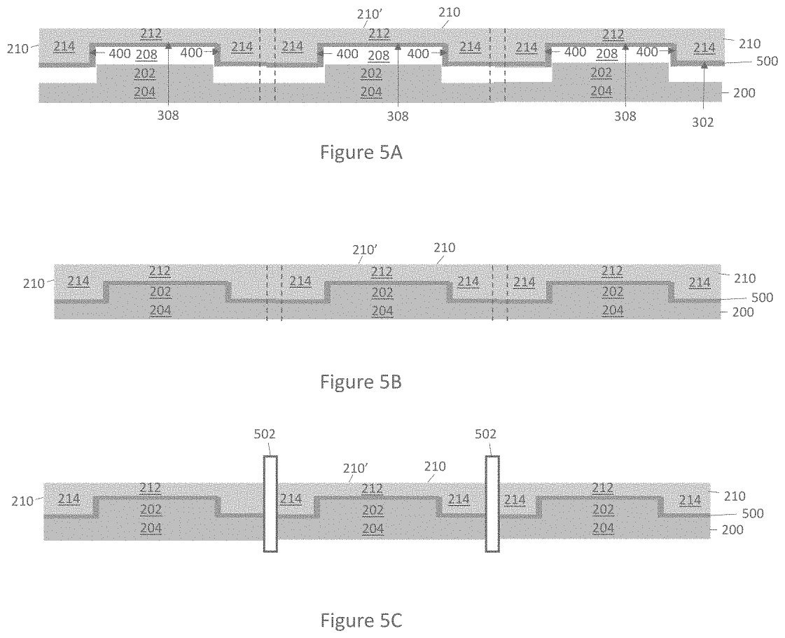

FIGS. 5A through 5C illustrate an embodiment of Blocks 120 through 140 of the method shown in FIG. 1, wherein the metal carrier is a leadframe 200. According to this embodiment, before placing the semiconductor dies 210 on the leadframe 200, a solder paste 500 is applied to the side 302 of each of the semiconductor dies 210 with the first cavity 208, as shown in FIG. 5A. This includes applying the solder paste 500 on the surface 308 of the 210 active region 212 facing the first cavity 208 of each of the semiconductor dies 210 and on the sidewalls 400 of the thicker inactive region 214 facing the first cavity 208 of each of the semiconductor dies 210.

After applying the solder paste 500, the semiconductor dies 210 are placed on the leadframe 200 so that each of the raised parts 202 of the die pads 204 of the leadframe 200 inserts into the respective first cavity 208 of the corresponding semiconductor die 210 and the leadframe 200 is attached to the semiconductor dies 210 by heating the paste 500 and forming a mechanical bond and electrical connection between the thinner active region 212 of each semiconductor die 210 and the leadframe 200, as shown in FIG. 5B. The leadframe 200 is then singulated by using a blade or similar tool 502 to cut through the leadframe 200 along the dicing streets indicated by the pairs of dashed lines shown in FIGS. 5A through 5C. As explained above in connection with FIGS. 1A through 1C, the semiconductor dies 210 may be singulated prior to attachment to the leadframe 200 or as part of the leadframe singulation process to form separate package assemblies.

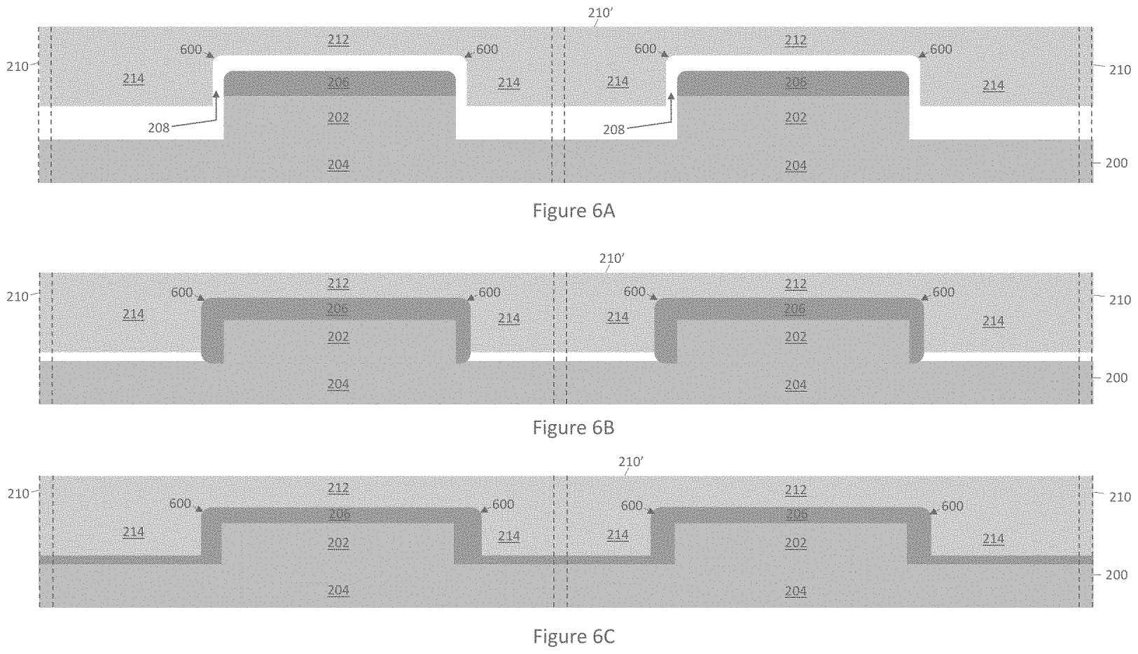

FIGS. 6A through 6C illustrate another embodiment of Blocks 110 through 130 of the method shown in FIG. 1, wherein the metal carrier is a leadframe 200. The processes shown in FIGS. 6A through 6C are similar to the processes shown in FIGS. 2A through 2C, respectively. Different, however, before placing the semiconductor dies 210 on the leadframe 200, the corners 600 of the first cavity 208 of each of the semiconductor dies 210 are rounded. The rounding may be achieved by a wet-chemical etching process or a plasma etch process, for example. As explained above in connection with FIGS. 1A through 1C, the semiconductor dies 210 may be singulated prior to attachment to the leadframe 200 or as part of the leadframe singulation process to form separate package assemblies.

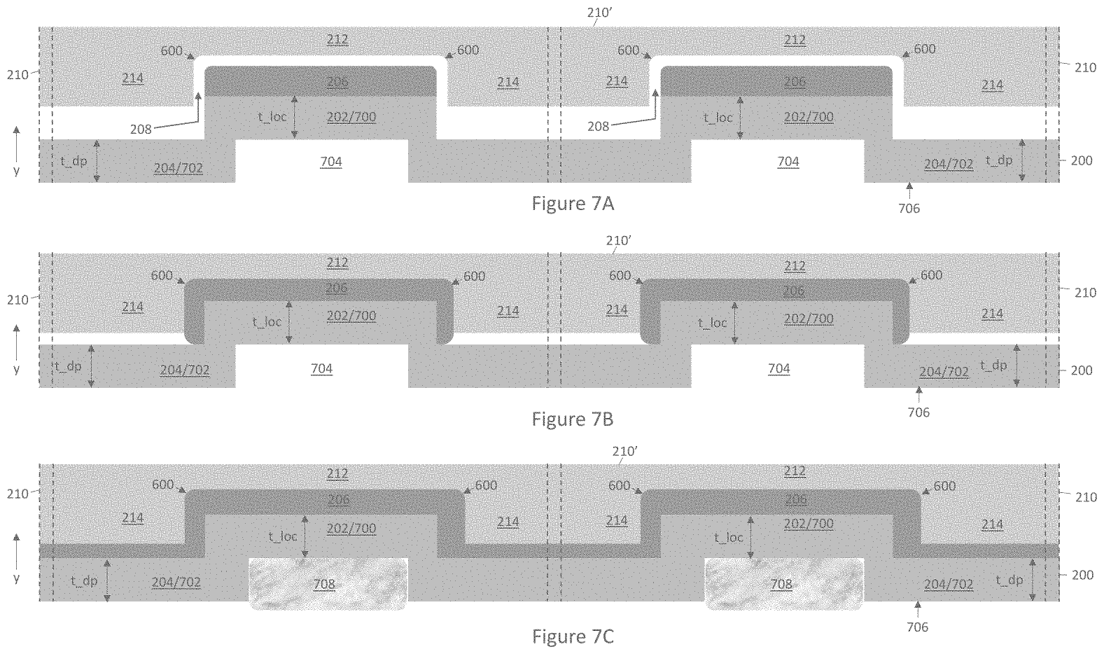

FIGS. 7A through 7C illustrate another embodiment of Blocks 110 through 130 of the method shown in FIG. 1, wherein the metal carrier is a leadframe 200. The processes shown in FIGS. 7A through 7C are the same as the processes shown in FIGS. 6A through 6C, respectively. Different, however, the raised parts 202 of the die pads 204 of the leadframe 200 bend upward in a direction (y) towards the semiconductor dies 210 so as to not have a local increase in thickness (t_loc) in a region 700 of the leadframe 200 adjacent to the thinner active regions 212 of the semiconductor dies 210. That is, the thickness t_loc of the region 700 of the leadframe 200 adjacent to the thinner active regions 212 of the semiconductor dies 210 is approximately equal to the thickness (t_dp) of a region 702 of the leadframe 200 adjacent to the thinner active regions 212 of the semiconductor dies 210. The leadframe profile illustrated in FIGS. 7A through 7C can be realized by stamping, etching, etc. of the leadframe 200. With this approach, cavities 704 are formed at the back side 706 of the leadframe 200 which are vertically aligned with the die cavities 208 and which may act as a reservoir for solder deposit 708. As explained above in connection with FIGS. 1A through 10, the semiconductor dies 210 may be singulated prior to attachment to the leadframe 200 or as part of the leadframe singulation process to form separate package assemblies.

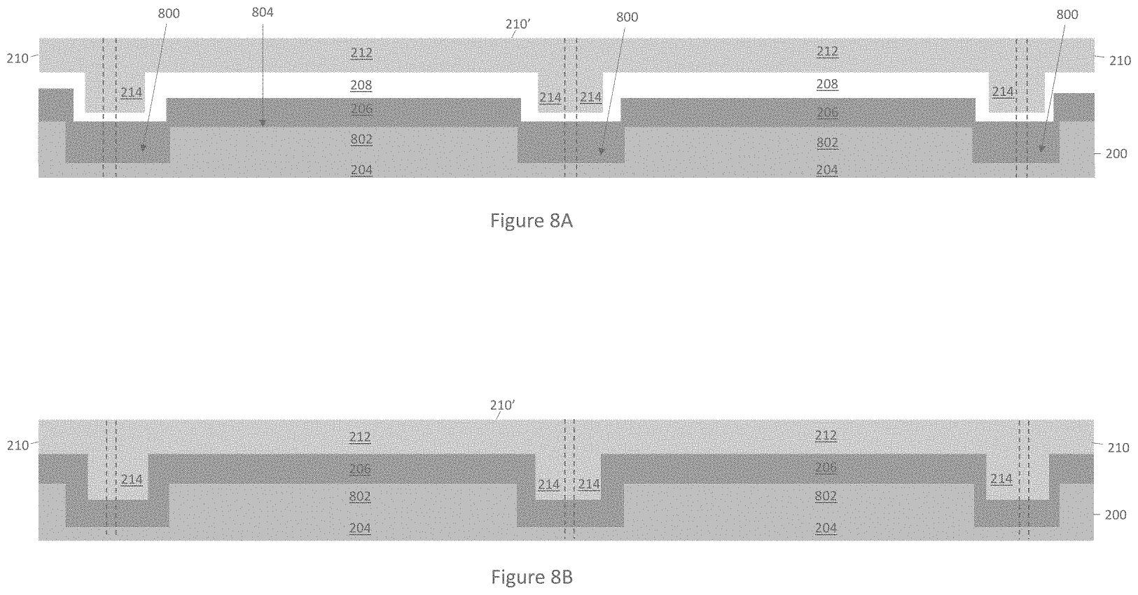

FIGS. 8A and 8B illustrate another embodiment of Blocks 110 through 130 of the method shown in FIG. 1, wherein the metal carrier is a leadframe 200. According to this embodiment, grooves 800 are formed in the leadframe 200 to form the connection parts 802 of the leadframe 200. The grooves 800 may be formed by etching, for example.

A die attach material 206 is applied to the side 804 of the leadframe 200 with the grooves 800, including in the grooves 800. After applying the die attach material 206, the semiconductor dies 210 are placed on the leadframe 200 so that the thicker inactive region 214 of each of the semiconductor dies 210 inserts into the groove 800 surrounding the corresponding connection part 802 of the leadframe 200 to which the semiconductor die 210 is to be attached, as shown in FIG. 8A. After the thicker inactive region 214 of each of the semiconductor dies 210 is inserted into the correspond groove 800 in the leadframe 200, the leadframe 200 is attached to the semiconductor dies 210 by soldering, sintering, gluing, etc., as shown in FIG. 8B. As explained above in connection with FIGS. 1A through 1C, the semiconductor dies 210 may be singulated prior to attachment to the leadframe 200 or as part of the leadframe singulation process to form separate package assemblies.

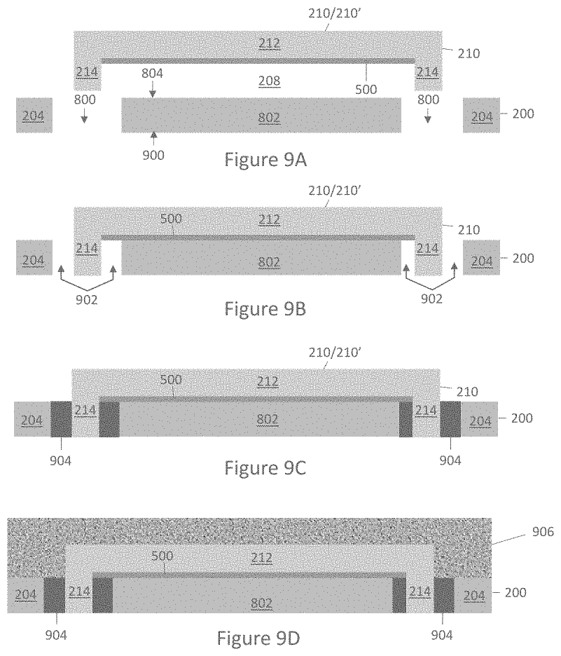

FIGS. 9A through 9D illustrate another embodiment of Blocks 110 through 130 of the method shown in FIG. 1, wherein the metal carrier is a leadframe 200. Similar to the embodiment shown in FIGS. 8A and 8B, grooves 800 are formed in the leadframe 200 to form the connection parts 802 of the leadframe 200. Different, however, the grooves 800 formed in the leadframe 200 shown in FIGS. 9A through 9D extend through the leadframe 200 from a first main surface 804 of the leadframe 200 to a second main surface 900 of the leadframe 200 opposite the first main surface 804, as shown in FIG. 9A. According to this embodiment, the thicker inactive region 214 of each of the semiconductor dies 210 is inserted into the groove 800 surrounding the corresponding connection part 802 of the leadframe 200 to which the semiconductor die 210 is to be attached, as shown FIG. 9B. After the inserting step, gaps 902 in the grooves 800 unoccupied by the thicker inactive region 214 of the semiconductor dies 210 are filled with an electrically insulating material 904, as shown in FIG. 9C. In one embodiment, the electrically insulating material is a mold compound. The semiconductor dies 210 and the side 804 of the leadframe 200 to which the semiconductor dies 210 are attached may then be encapsulated with an encapsulation material 906, as shown in FIG. 9D. The encapsulation material 906 may be a molding compound, a glob top, a dielectric laminate film, a casting resin or a simple polymer coating. The encapsulation material 906 may at least partially be an epoxy resin, an acrylic resin, a silicone polymer or a thermoplastic polymer. The encapsulation material 906 may contain fillers like SiO₂, Al₂O₃, BN or any other inorganic filler particle. In addition, the encapsulation material 906 may be any inorganic material like a ceramic material, a cement or an inorganic coating layer. In FIGS. 9A through 9D, the semiconductor dies 210 were singulated prior to attachment to the leadframe 200. However, as explained above in connection with FIGS. 1A through 1C, the semiconductor dies 210 instead may be singulated as part of the leadframe singulation process to form separate package assemblies.

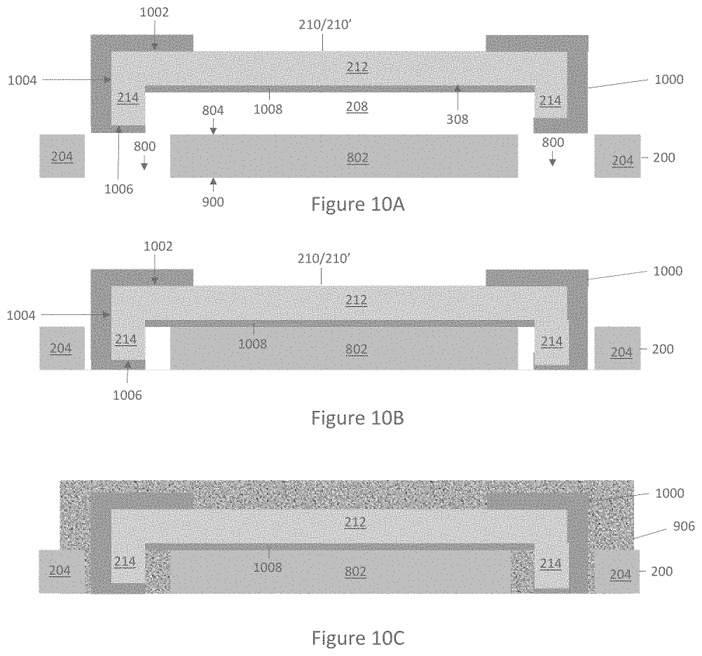

FIGS. 10A through 10C illustrate another embodiment of Blocks 110 through 130 of the method shown in FIG. 1, wherein the metal carrier is a leadframe 200. According to this embodiment, a first electrically conductive material 1000 is applied to a front side 1002, an outer edge 1004 and a backside 1006 of the semiconductor dies 210, as shown in FIG. 10A. The first electrically conductive material 1000 provides an electrical connection to the front side 1002 from the backside 1006 of the semiconductor dies 210, along the outer edge 1004. The first electrically conductive material 1000 may contain at least one of the metals Ag, Cu, Ni, Sn, Al, Au or a combination thereof.

A second electrically conductive material 1008 is applied to the surface 308 of the thinner active region 212 facing the first cavity 208 of each of the semiconductor dies 210, also as shown in FIG. 10A. The second electrically conductive material 1008 is electrically isolated from the first electrically conductive material 1000. The second electrically conductive material 1008 may be a thin metal layer or an electrically conductive paste, like a solder paste, a sinter paste or an adhesive paste, and may contain at least one of the metals Ag, Cu, Ni, Sn, Al, Au or a combination thereof.

After applying the first and the second electrically conductive materials 1000, 1008, the thicker inactive region 214 of each of the semiconductor dies 210 is inserted into the groove 800 surrounding the corresponding connection part 802 of the leadframe 200 to which the semiconductor die 210 is to be attached, as shown in FIG. 10B. After the inserting into the grooves 800, the semiconductor dies 210 and the side 804 of the leadframe 200 to which the semiconductor dies 210 are attached is encapsulated with an encapsulation material 906, as shown in FIG. 100. In FIGS. 10A through 10C, the semiconductor dies 210 were singulated prior to attachment to the leadframe 200. However, as explained above in connection with FIGS. 1A through 1C, the semiconductor dies 210 instead may be singulated as part of the leadframe singulation process to form separate package assemblies.

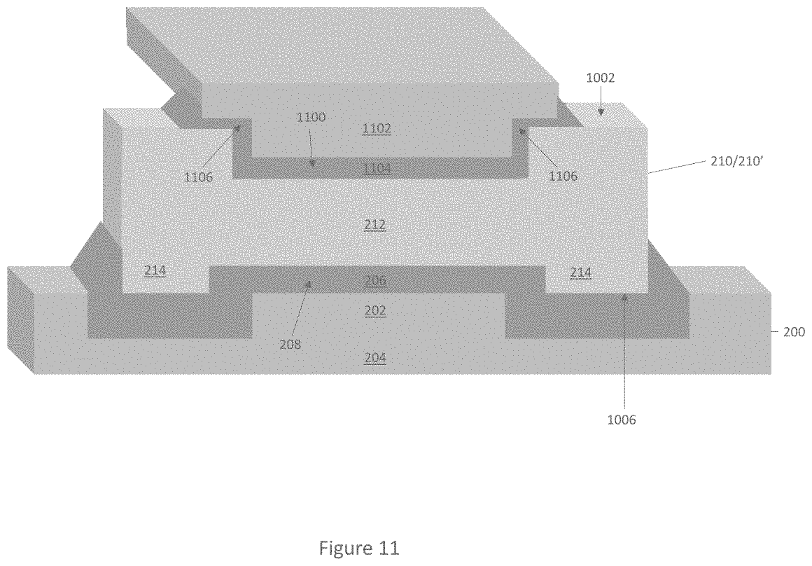

FIG. 11 illustrates another embodiment of Blocks 110 through 130 of the method shown in FIG. 1, wherein the metal carrier is a leadframe 200. According to this embodiment, a second cavity 1100 is formed in each of the semiconductor dies 210 at an opposite side 1002 of the semiconductor dies 210 as the first cavity 208. The second cavity 1100 is vertically aligned with the thinner active region 212 and the first cavity 208, and laterally surrounded by the thicker inactive region 214. A separate metal clip 1102 is inserted into the respective second cavity 1100 of each of the semiconductor dies 210. The metal clip 1102 is attached to the semiconductor die 210 by another die attach material 1104 which may be the same or different than the first die attach material 206. In one embodiment, the metal clip 1102 extends over the thicker inactive region 214 of the semiconductor die 210 and has a notch 1106 extending into the second cavity 1100. In FIG. 11, the semiconductor dies 210 were singulated prior to attachment to the leadframe 200. However, as explained above in connection with FIGS. 1A through 1C, the semiconductor dies 210 instead may be singulated as part of the leadframe singulation process to form separate package assemblies.

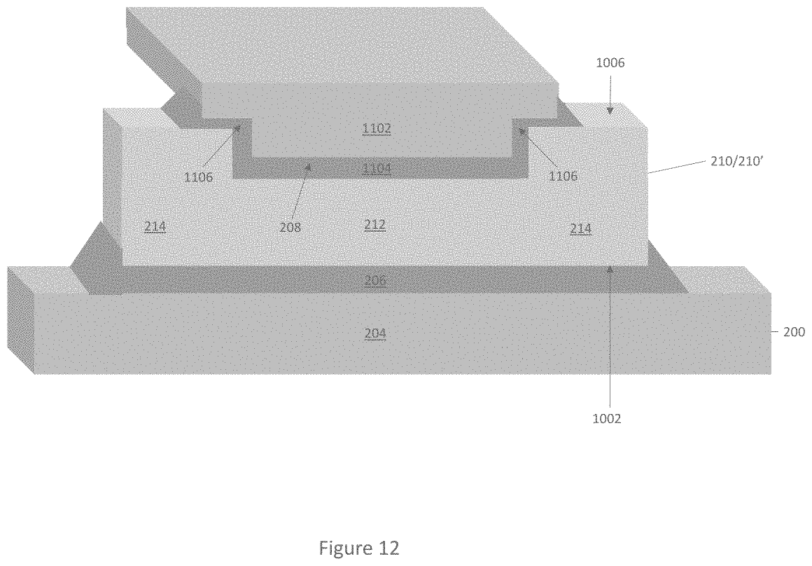

FIG. 12 illustrates another embodiment of Blocks 110 through 130 of the method shown in FIG. 1, wherein the metal carrier is a leadframe 200. The embodiment illustrated in FIG. 12 is similar to the embodiment illustrated in FIG. 11. Different, however, the semiconductor die 210 is attached to a planar part of the leadframe 200 in a flip-chip configuration with the front side 1002 facing the leadframe 200 and has a single cavity 208 at the die backside 1006 into which the metal clip 1102 may be inserted. According to this embodiment, the semiconductor die 210 is placed topside-down, e.g., on a flat die pad 204 of the leadframe 200 so that the top side 1002 of the die 210 is attached to the die pad 204 with a die attach material 206. The metal clip 1102 may be placed in the cavity 208 at the backside 1006 of each semiconductor die 210, and attached with a second material 1104 which may be the same or different as the die attach material 206 used to attach the die 210 in a flip-chip configuration to the leadframe 200. With this configuration, and in the case of a vertical power transistor as the semiconductor die 210, the metal clip 1102 may provide a drain connection and at the same time provides top-side cooling for the semiconductor device.

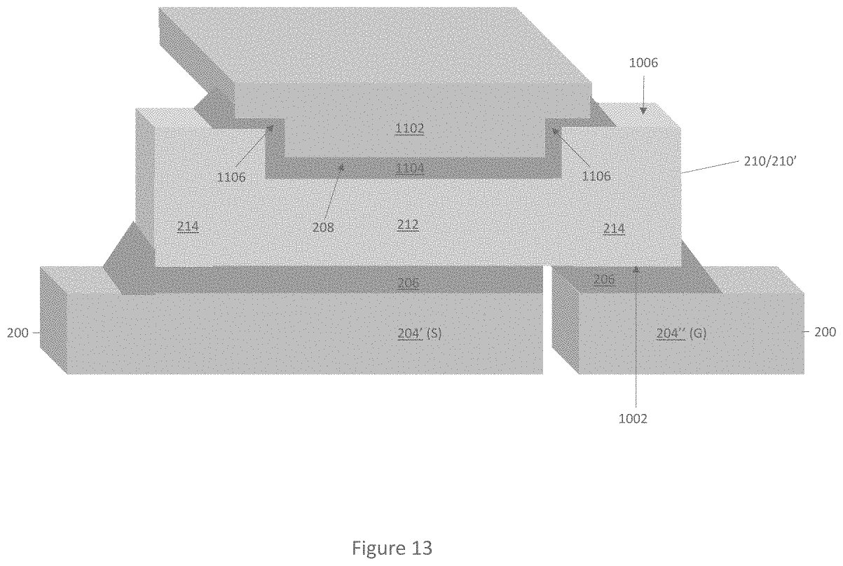

FIG. 13 illustrates another embodiment of Blocks 110 through 130 of the method shown in FIG. 1, wherein the metal carrier is a leadframe 200. The embodiment illustrated in FIG. 13 is similar to the embodiment illustrated in FIG. 12. According to the embodiment illustrated in FIG. 13, the die pad 204 is segmented into separate sections 204′, 204″ to differentiate between gate (G) and source connections (S), e.g., in the case of a vertical power transistor as the semiconductor die 210.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method, comprising:
providing a plurality of semiconductor dies, each of the semiconductor dies having a thinner active region surrounded by a thicker inactive region so that each of the semiconductor dies has a first cavity vertically aligned with the thinner active region and laterally surrounded by the thicker inactive region;
providing a metal carrier having connection parts secured to the metal carrier, each of the connection parts dimensioned to fit within the first cavity of one of the semiconductor dies;
inserting each of the connection parts of the metal carrier into the respective first cavity of the corresponding semiconductor die;
after the inserting, attaching the metal carrier to the semiconductor dies; and
after the attaching, singulating the metal carrier so that each of the connection parts of the metal carrier remains attached to the corresponding semiconductor die.

2. The method of claim 1, wherein the metal carrier is a leadframe, and wherein the connection parts of the metal carrier are raised parts of die pads of the leadframe.

3. The method of claim 2, wherein inserting each of the connection parts of the metal carrier into the respective first cavity of the corresponding semiconductor die comprises:
applying a die attach material to the raised parts of the die pads of the leadframe; and
after applying the die attach material, inserting each of the raised parts into the respective first cavity of the corresponding semiconductor die.

4. The method of claim 3, further comprising:
before the inserting, forming a thin metallization layer on a surface of the thinner active region facing the first cavity of each of the semiconductor dies.

5. The method of claim 4, further comprising:
forming the thin metallization layer on sidewalls of the thicker inactive region facing the first cavity of each of the semiconductor dies.

6. The method of claim 3, further comprising:
before placing the inserting, applying a solder paste to a side of each of the semiconductor dies with the first cavity, including on a surface of the thinner active region facing the first cavity of each of the semiconductor dies and on sidewalls of the thicker inactive region facing the first cavity of each of the semiconductor dies.

7. The method of claim 3, further comprising:
before placing the inserting, rounding interior corners of the first cavity of each of the semiconductor dies.

8. The method of claim 2, wherein the raised parts of the die pads of the leadframe bend upward in a direction towards the semiconductor dies so as to not have a local increase in thickness in a region adjacent to the thinner active regions of the semiconductor dies.

9. The method of claim 1, wherein the metal carrier is a leadframe, and wherein the connection parts of the metal carrier are surrounded by grooves formed in the leadframe.

10. The method of claim 9, wherein inserting each of the connection parts of the metal carrier into the respective first cavity of the corresponding semiconductor die comprises:
applying a die attach material to a side of the leadframe with the grooves, including in the grooves; and
after applying the die attach material, inserting the thicker inactive region of each of the semiconductor dies into the groove surrounding the corresponding connection part of the leadframe to which the semiconductor die is to be attached.

11. The method of claim 9, wherein the grooves extend through the leadframe from a first main surface of the leadframe to a second main surface of the leadframe opposite the first main surface.

12. The method of claim 11, wherein inserting each of the connection parts of the metal carrier into the respective first cavity of the corresponding semiconductor die comprises:
inserting the thicker inactive region of each of the semiconductor dies into the groove surrounding the corresponding connection part of the leadframe to which the semiconductor die is to be attached.

13. The method of claim 12, further comprising:
after the inserting, filling gaps in the grooves unoccupied by the thicker inactive region of the semiconductor dies with an electrically insulating material.

14. The method of claim 9, wherein inserting each of the connection parts of the metal carrier into the respective first cavity of the corresponding semiconductor die comprises:
applying a first electrically conductive material to a top side, an outer edge and a bottom side of the semiconductor dies, to provide an electrical connection to the top side from the bottom side of the semiconductor dies;
applying a second electrically conductive material to a surface of the thinner active region facing the first cavity of each of the semiconductor dies, the second electrically conductive material being electrically isolated from the first electrically conductive material; and
after applying the first and the second electrically conductive materials, inserting the thicker inactive region of each of the semiconductor dies into the groove surrounding the corresponding connection part of the leadframe to which the semiconductor die is to be attached.

15. The method of claim 1, further comprising:
forming a second cavity in each of the semiconductor dies at an opposite side of the semiconductor dies as the first cavity, the second cavity being vertically aligned with the thinner active region and the first cavity and laterally surrounded by the thicker inactive region; and
inserting a separate metal clip into the respective second cavity of each of the semiconductor dies.

16. A semiconductor device, comprising:
a semiconductor die having a thinner active region surrounded by a thicker inactive region, and a first cavity vertically aligned with the thinner active region and laterally surrounded by the thicker inactive region; and
a die pad of a leadframe positioned at least partly within the first cavity so as to at least partly occupy the first cavity, the die pad being attached to the semiconductor die.

17. The semiconductor device of claim 16, wherein the semiconductor die has a second cavity at an opposite side of the semiconductor die as the first cavity, the second cavity being vertically aligned with the thinner active region and the first cavity and laterally surrounded by the thicker inactive region, the semiconductor device further comprising a metal clip positioned at least partly within the second cavity so as to at least partly occupy the second cavity, the metal clip being attached to the semiconductor die.

18. The semiconductor device of claim 17, wherein the metal clip extends over the thicker inactive region of the semiconductor die and has a notch extending into the second cavity.

19. A semiconductor device, comprising:
a leadframe;
a semiconductor die attached to the leadframe in a flip-chip configuration with a front side of the semiconductor die facing the leadframe, the semiconductor die having a thinner active region surrounded by a thicker inactive region, and a cavity formed in a backside of the semiconductor die, the cavity being vertically aligned with the thinner active region and laterally surrounded by the thicker inactive region; and
a metal clip inserted in the cavity and attached to the backside of the semiconductor die.

20. The semiconductor device of claim 19, wherein the semiconductor die is a vertical power transistor die, and wherein the metal clip provides a drain connection to the backside of the semiconductor die and provides top-side cooling for the semiconductor device.

21. The semiconductor device of claim 19, wherein the semiconductor die is a vertical power transistor die, wherein the leadframe is segmented into a plurality of separate sections, wherein a first section of the plurality of separate sections provides a source connection to the semiconductor die, and wherein a second section of the plurality of separate sections provides a gate connection to the semiconductor die.
